(19) United States
(12) Patent Application Publication
(10) Pub. No.: US 2023/0106020 A1
(43) Pub. Date: Apr. 6, 2023

(54) LIGHT-EMITTING DIODE CHIP AND METHOD FOR MANUFACTURING THE SAME

(71) Applicant: EPILEDS TECHNOLOGIES, INC., Tainan City (TW)

(72) Inventors: Li-Wei HUNG, Tainan City (TW); Hsin-Liang YEH, Tainan City (TW); Wei-Chen CHIEN, Tainan City (TW); Zhen-Jin WANG, Tainan City (TW)

(21) Appl. No.: 17/457,438

(22) Filed: Dec. 3, 2021

(30) Foreign Application Priority Data
Sep. 24, 2021 (TW) 110135670

(51) Int. Cl. H01L 33/38; H01L 25/075; H01L 33/00; H01L 33/62

(52) U.S. Cl. CPC H01L 33/382; H01L 25/0753; H01L 33/005; H01L 33/62; H01L 2933/0016; H01L 2933/0066

(57) ABSTRACT

A light-emitting diode chip is described. The light-emitting diode chip includes a light-emitting structure, a first electrode, and a second electrode. The first electrode is disposed on the light-emitting structure and is electrically connected to the light-emitting structure. The second electrode is disposed on the light-emitting structure, and the second electrode and the first electrode are located on the same side of the light-emitting structure, wherein the second electrode is electrically connected to the light-emitting structure. The light-emitting diode chip has a first surface and a second surface which are opposite to each other, and a side surface connected between the first surface and the second surface. The side surface is substantially perpendicular to the first surface and the second surface, and an included angle between the side surface and the first surface is between 86 degrees and 94 degrees.

### RELATED APPLICATIONS

This application claims priority to Taiwan Application Serial Number 110135670, filed Sep. 24, 2021, which is herein incorporated by reference.

### BACKGROUND

### Field of Invention

The present disclosure relates to a technique for manufacturing a light-emitting device, and more particularly, to a light-emitting diode (LED) chip and a method for manufacturing the same.

### Description of Related Art

A micro light-emitting diode display technique is to miniaturize and array light-emitting diode chips, and each light-emitting diode chip is used as a display pixel, such that each pixel can be addressed and individually driven to light up. Due to the excellent display function, low power consumption, thin thickness, and long life of the micro light-emitting diode display, it has been regarded as the next generation of display technique.

In the manufacturing of micro light-emitting diode display, the micro light-emitting diode chips need to be addressed and mass transferred to a circuit board. At present, transfer techniques of the micro light-emitting diode chips mainly include stamp pick and place, electrostatic adsorption, wafer bonding, roll to plate, fluid assembly, antimagnetic floating, and laser release. However, these mass transfer techniques are immature and cannot meet the efficiency and yield required for commercial production of micro light-emitting diode displays.

### SUMMARY

Therefore, one objective of the present disclosure is to provide a light-emitting diode chip, in which outer contours of an upper surface and a lower surface of the light-emitting diode chip are substantially the same in shape and size, and the light-emitting diode chip is not a type of wide top and a narrow bottom, such that it can prevent the light-emitting diode chip from tilting during transferring, thereby enhancing the transfer efficiency of the light-emitting diode chip.

Another objective of the present disclosure is to provide a light-emitting diode chip and a method for manufacturing the same, in which a side surface of the light-emitting diode chip is substantially perpendicular to the upper surface and the lower surface, such that the light-emitting diode chips do not block each other when they are assembled in fluid, thereby further enhancing the assembly efficiency of the light-emitting diode chips.

Still another objective of the present disclosure is to provide a light-emitting diode chip and a method for manufacturing the same, in which sidewalls of the light-emitting diode chips are substantially vertical, such that when these light-emitting diode chips are assembled on a circuit board, the spacing between the light-emitting diode chips is effectively decreased, and thus it can make the display have better color rendering, and can also reduce the light interference between the light-emitting diode chips of different colors. Moreover, the substantially vertical sidewall has a stronger structure, such that it can prevent the light-emitting diode chips from being damaged during the transfer process.

Still further another objective of the present disclosure is to provide a method for manufacturing a light-emitting diode chip, which may use barrier layers of different materials to modify a sidewall of the light-emitting diode chip, such that the light-emitting diode chip with a substantially vertical sidewall can be obtained successfully after an inductively coupled plasma (ICP) etching without other processing. Therefore, the process complexity is reduced, the process time is decreased, and productivity and yield can be increased.

According to the aforementioned objectives of the present disclosure, a light-emitting diode chip is provided. The light-emitting diode chip includes a light-emitting structure, a first electrode, and a second electrode. The first electrode is disposed on the light-emitting structure and is electrically connected to the light-emitting structure. The second electrode is disposed on the light-emitting structure and is located on a same side of the light-emitting structure as the first electrode, in which the second electrode is electrically connected to the light-emitting structure. The light-emitting diode chip has a first surface and a second surface which are opposite to each other, and a side surface connected between the first surface and the second surface, and the side surface is substantially perpendicular to the first surface and the second surface.

According to one embodiment of the present disclosure, a substantially vertical included angle between the side surface and the first surface is between 86 degrees and 94 degrees.

According to one embodiment of the present disclosure, a substantially vertical included angle between the side surface and the first surface is between 88 degrees and 92 degrees.

According to one embodiment of the present disclosure, a length or a diameter of the light-emitting diode chip is less than 50 µm, and a thickness of the light-emitting diode chip is between 4 µm and 12 µm.

According to one embodiment of the present disclosure, a longer one and a short one of the first surface and the second surface respectively have a first length and a second length, a difference between the first length and the second length divided by two is equal to or greater than 0, and a difference between the first length and the second length divided by two is equal to or smaller than a height of the light-emitting diode chip divided by an absolute value of cot(a difference between 90 degrees and an included angle between the longer one and the side surface).

According to one embodiment of the present disclosure, outer contours of the first surface and the second surface are substantially the same in shape and size.

According to one embodiment of the present disclosure, a shape of the light-emitting diode chip is a circle or a symmetrical polygon.

According to one embodiment of the present disclosure, the light-emitting structure includes a first conductive type semiconductor layer, a second conductive type semiconductor layer, and a light-emitting layer sandwiched between the first conductive type semiconductor layer and the second conductive type semiconductor layer, in which the first electrode is electrically connected to the first conductive type semiconductor layer, and the second electrode is electrically connected to the second conductive type semiconductor layer.

According to the aforementioned objectives of the present disclosure, a method for manufacturing a light-emitting diode chip is further provided. In this method, a light-emitting structure body is formed on a growth substrate. At least one barrier layer is formed on the light-emitting structure body. An etching process is performed through the at least one barrier layer to remove a portion of the light-emitting structure body so as to form various light-emitting structures and to expose a portion of the growth substrate, in which each of the light-emitting structures includes a second conductive type semiconductor layer, a light-emitting layer, and a first conductive type semiconductor layer sequentially stacked on the growth substrate. A first portion of the first conductive type semiconductor layer of the each of the light-emitting structures and the underlying light-emitting layer are removed until a first portion of the second conductive type semiconductor layer is exposed. Various first electrodes are respectively formed on various second portions of the first conductive type semiconductor layers of the light-emitting structures. Various second electrodes are respectively formed on the first portions of the second conductive type semiconductor layers of the light-emitting structures to form various light-emitting diode chips. Each of the light-emitting diode chips has a first surface and a second surface which are opposite to each other, and a side surface connected between the first surface and the second surface, and the side surface is substantially perpendicular to the first surface and the second surface. The light-emitting diode chips are bonded onto a temporary substrate by using an adhesive layer. The growth substrate is removed to expose the second conductive type semiconductor layers.

According to one embodiment of the present disclosure, the at least one barrier layer is a compound composed of any combination of group III, group IV, and group V.

According to one embodiment of the present disclosure, the etching process is an inductively coupled plasma reactive ion etching process.

According to one embodiment of the present disclosure, outer contours of the first surface and the second surface of each of the light-emitting diode chips are substantially the same in shape and size.

According to one embodiment of the present disclosure, a shape of each of the light-emitting diode chips is a circle or a symmetrical polygon.

According to one embodiment of the present disclosure, in each of the light-emitting diode chips, a substantially vertical included angle between the side surface and the first surface is between 86 degrees and 94 degrees.

According to one embodiment of the present disclosure, in each of the light-emitting diode chips, a substantially vertical included angle between the side surface and the first surface is between 88 degrees and 92 degrees.

According to one embodiment of the present disclosure, in each of the light-emitting diode chips, a longer one and a short one of the first surface and the second surface respectively have a first length and a second length, a difference between the first length and the second length divided by two is equal to or greater than 0, and a difference between the first length and the second length divided by two is equal to or smaller than a height of the light-emitting diode chip divided by an absolute value of cot(a difference between 90 degrees and an included angle between the longer one and the side surface).

### BRIEF DESCRIPTION OF THE DRAWINGS

The aforementioned and other objectives, features, advantages and examples of the present disclosure can be more fully understood by reading the following detailed description of the embodiment, with reference made to the accompanying drawings as follows:

FIGS. 1 to 6 are schematic cross-sectional views of various stages in manufacturing of a light-emitting diode chip in accordance with one embodiment of the present disclosure; and

FIG. 7 is a side view of a light-emitting diode chip in accordance with one embodiment of the present disclosure.

### DETAILED DESCRIPTION

The following disclosure provides many different embodiments for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features.

Spatially relative terms, such as “beneath,” “below,” “lower,” “above,” “upper,” and the like, may be used herein for ease of description to describe one element or feature’s relationship to another element(s) or feature(s) as illustrated in the figures. In addition to the orientation depicted in the figures, the spatially relative terms are intended to encompass different orientations of the device in use or operation.

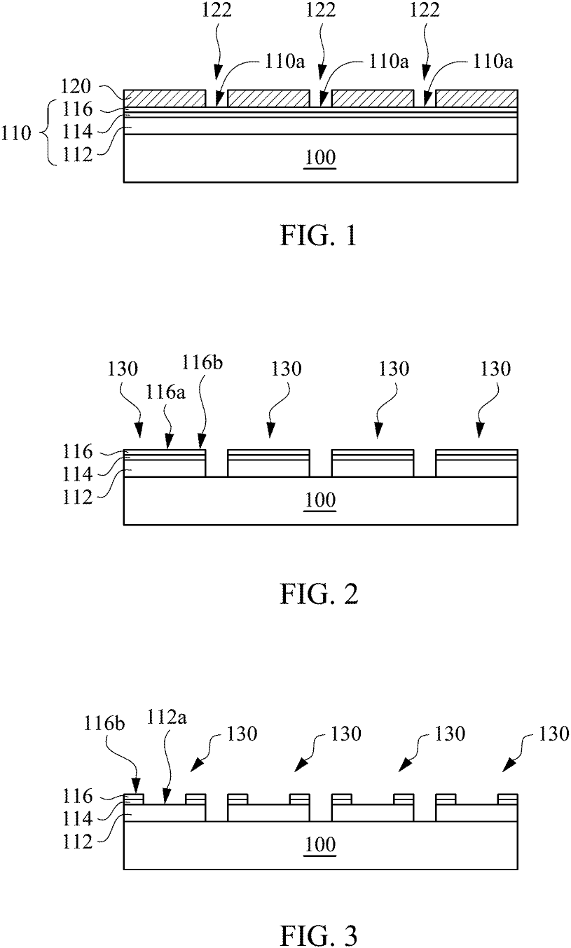

Refer to FIGS. 1 to 6. FIGS. 1 to 6 are schematic cross-sectional views of various stages in manufacturing of a light-emitting diode chip in accordance with one embodiment of the present disclosure. In manufacturing a light-emitting diode chip, a growth substrate 100 can be provided first. For example, a material of the growth substrate 100 may be gallium nitride (GaN), gallium arsenide (GaAs), silicon, silicon carbide (SiC), or sapphire (Al₂O₃).

A light-emitting structure body 110 is grown on the growth substrate 100 by using, for example, an epitaxial growth method. In some examples, the light-emitting structure body 110 mainly includes a second conductive type semiconductor layer 112, a light-emitting layer 114, and a first conductive type semiconductor layer 116 sequentially stacked on the growth substrate 100. For example, in the growing of the light-emitting structure body 110, the second conductive type semiconductor layer 112 may be epitaxially grown on the growth substrate 100 firstly, the light-emitting layer 114 may be epitaxially grown on the second conductive type semiconductor layer 112, and then the first conductive type semiconductor layer 116 may be epitaxially grown on the light-emitting layer 114. Thus, the light-emitting layer 114 is sandwiched between the second conductive type semiconductor layer 112 and the first conductive type semiconductor layer 116.

The second conductive type semiconductor layer 112 and the first conductive type semiconductor layer 116 have different conductive types. One of the second conductive type semiconductor layer 112 and the first conductive type semiconductor layer 116 may be N type, and the other one may be P type. For example, the second conductive type semiconductor layer 112 is N type, and the first conductive type semiconductor layer 116 is P type. Materials of the second conductive type semiconductor layer 112 and the first conductive type semiconductor layer 116 may include gallium nitride (GaN) or GaN-based materials. For example, the light-emitting layer 114 may be a multiple quantum well (MQW) structure. In some exemplary examples, the light-emitting layer 114 is formed by alternatively stacking GaN and GaN-based materials.

Next, at least one barrier layer 120 is formed on the first conductive type semiconductor layer 116 of the light-emitting structure body 110. For example, the barrier layer 120 may be a compound composed of any combination of group III, such as boron (B), aluminum (Al), gallium (Ga), indium (In), thallium (Tl), and nihonium (Nh); group IV, such as carbon (C), silicon (Si), germanium (Ge), tin (Sn), lead (Pb), and flerovium (Fl); and group V, such as nitrogen (N), phosphorus (P), arsenic (As), antimony (Sb), bismuth (Bi), and moscovium (Mc). As shown in FIG. 1, the barrier 120 has various openings 122, in which these openings 122 respectively expose various portions 110a of the light-emitting structure body 110. In some examples, these openings 122 are regularly arranged in the barrier layer 120 at a predetermined interval.

After the formation of the barrier layer 120 is completed, an etching process may be performed through the barrier layer 120 to remove a portion of the light-emitting structure body 110, that is a portion of the first conductive type semiconductor layer 116, a portion of the light-emitting layer 114, and a portion of the second conductivity type semiconductor layer 112, until a portion of the growth substrate 100 is exposed. Thus, the light-emitting structure body 110 can be divided into various light-emitting structures 130, as shown in FIG. 2. That is, each of the light-emitting structures 130 includes the second conductive type semiconductor layer 112, the light-emitting layer 114, and the first conductive type semiconductor layer 116 sequentially stacked on the growth substrate 100. After the etching process is performed, any suitable removal technique may be used to remove the barrier layer 120 according to the material of the barrier layer 120. In some exemplary examples, the etching process may be an inductively coupled plasma reactive ion etching process.

Next, a first portion 116a of the first conductive type semiconductor layer 116 and the underlying light-emitting layer 114 of each of the light-emitting structures 130 are removed by using, for example, an etching technique, until a first portion 112a of the second conductive type semiconductor layer 112 is exposed, as shown in FIG. 3. The exposed first portion 112a of the second conductivity type semiconductor layer 112 can be provided to fabricate an electrode thereon. After being removed, the second portion 116b of the first conductivity type semiconductor layer 116 and the underlying light-emitting layer 114 are left. The exposed second portion 116b of the first conductivity type semiconductor layer 116 can be provided to fabricate another electrode thereon.

A first electrode 140 may be formed on the second portion 116b of each of the first conductive type semiconductor layer 116 by using, for example, an evaporation deposition. Thus, the first electrode 140 is electrically connected to the first conductive type semiconductor layer 116. For example, a material of the first electrode 140 may include any one of titanium (Ti), nickel (Ni), aluminum (Al), palladium (Pd), rhodium (Rh), platinum (Pt), gold (Au), and chromium (Cr) or an alloy structure thereof.

Similarly, a second electrode 150 may be formed on the exposed first portion 112a of each of the second conductive type semiconductor layer 112 by using, for example, an evaporation deposition, so as to form light-emitting diode chips 160. Thus, the second electrode 150 is electrically connected to the second conductive type semiconductor layer 112. The second electrode 150 is formed only on a portion of the first portion 112a of the second conductivity type semiconductor layer 112, and is separated from the second portion 116b of the first conductivity type semiconductor layer 116 and the underlying light emitting layer 114. For example, a material of the second electrode 150 may include any one of Ti, Ni, Al, Pd, Rh, Pt, Au, and Cr or an alloy structure thereof. In some exemplary examples, viewing from top of the light-emitting diode chip 160, the second electrode 150 may be circular, and the first electrode 140 may be a ring-shaped structure surrounding the second electrode 150.

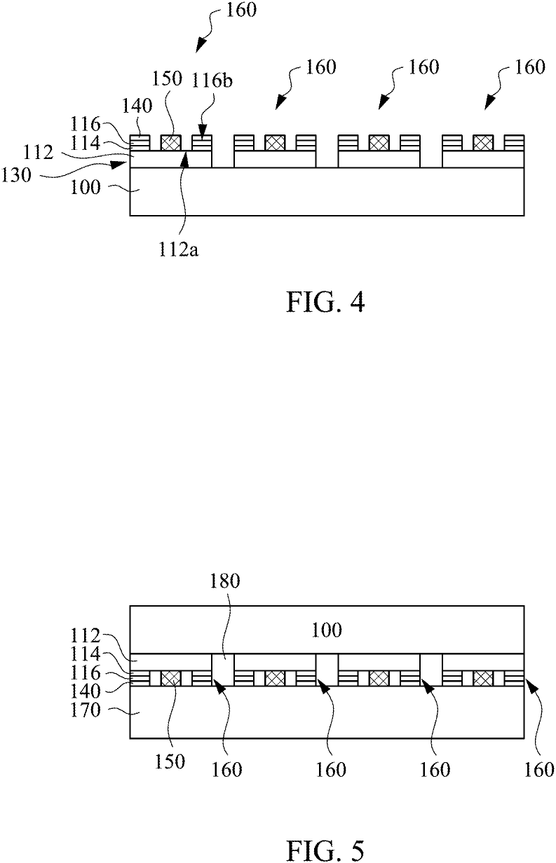

Then, a temporary substrate 170 is provided, the structure shown in FIG. 4 is turned upside down, and light-emitting diode chips 160 are bonded onto the temporary substrate 170 by using an adhesive layer 180, as shown in FIG. 5. The temporary substrate 170 may be any substrate that can provide support for the light-emitting diode chips 160 to facilitate the subsequent removal of the growth substrate 100.

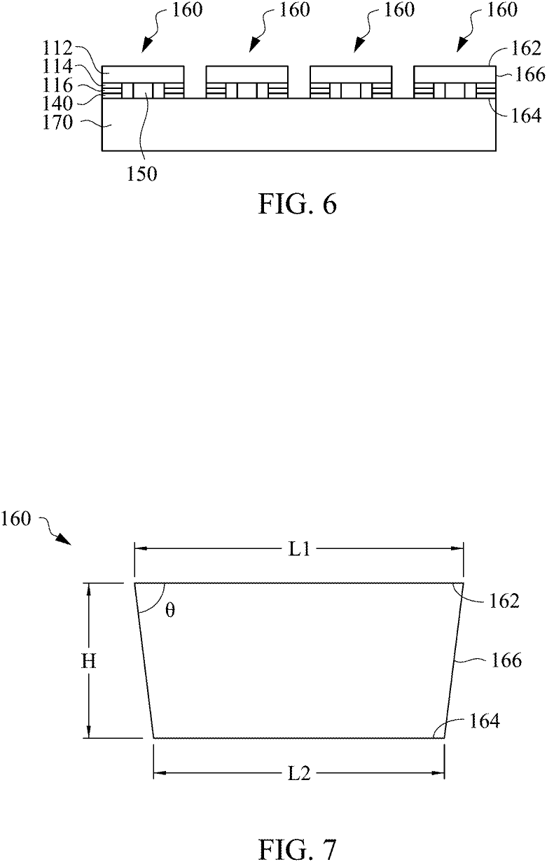

After the light-emitting diode chips 160 are bonded to the temporary substrate 170, the temporary substrate 170 can be used as a support to remove the growth substrate 100. As shown in FIG. 6, after the growth substrate 100 is removed, the second conductivity type semiconductor layer 112 of each of the light-emitting diode chips 160 is exposed. In some exemplary examples, the growth substrate 100 may be peeled off by using a laser lift-off method. Any type of laser, such as diode-pumped solid-state laser (DPSS) or excimer laser, can be used to strip the growth substrate 100.

Subsequently, the adhesive layer 180 may be removed to substantially complete the manufacturing of the light-emitting diode chips 160 on the temporary substrate 170, as shown in FIG. 6. In some examples, a length or a diameter of each of the light-emitting diode chips 160 is less than about 50 µm, and a thickness of each of the light-emitting diode chips 160 is between about 4 µm and about 12 µm. In addition, a shape of each of the light-emitting diode chips 160 may be a circle or a symmetrical polygon, such as a square and a rectangle.

Referring to FIG. 6 continuously, each of the light-emitting diode chips 160 has a first surface 162, a second surface 164, and a side surface 166, in which the first surface 162 and the second surface 164 are respectively located on two opposite sides of the light-emitting diode chip 160 and are opposite to each other, and the side surface 166 is connected between the first surface 162 and the second surface 164. In the present embodiment, in the etching process, the material combination of the barrier layer 120 is designed, so that each of the light-emitting diode chips 160 has a substantially vertical sidewall. That is, in the light-emitting diode chip 160, the first surface 162 and the second surface 164 may be parallel to each other, and an orthographic projection of the first surface 162 to the second surface 164 is substantially completely overlapped with the second surface 164, i.e., outer contours of the first surface 162 and the second surface 164 have substantially the same shape and size. In addition, the side surface 166 is substantially perpendicular to the first surface 162 and the second surface 164. That is, an included angle between the side surface 166 and the first surface 162 and an included angle between the side surface 166 and the second surface 164 are substantially right angles, for example, between about 86 degrees and about 94 degrees. For example, the substantially right angle between the side surface 166 and the first surface 162 is between about 88 degrees and about 92 degrees.

Refer to FIG. 7. FIG. 7 is a side view of a light-emitting diode chip in accordance with one embodiment of the present disclosure. In the example shown in FIG. 7, the first surface 162 of the light-emitting diode chip 160 is slightly longer than the second surface 164, the first surface 162 has a first length L1, and the second surface 164 has a second length L2. The light emitting diode chip 160 has a height H. There is an included angle θ between the first surface 162 and the side surface 166. In some examples, the relationship between the first length L1, the second length L2, the height H, and the included angle θ is

$$0 \leq \frac{\text{L1} - \text{L2}}{2} \leq \frac{\text{H}}{\left|\text{cot} \left({90}^{∘} - θ\right)\right|} .$$

It can be understood that when the shape of the light emitting diode chip 160 is circular, the first length L1 and the second length L2 are diameters. When the shape of the light emitting diode chip 160 is rectangle, the first length L1 and the second length L2 are side lengths.

In the present embodiment, the barrier structure can be used to modify the sidewall of the light-emitting diode chip 160, such that the light-emitting diode chip 160 with the substantially vertical sidewall can be successfully obtained after etching while the thickness of the light-emitting diode chip 160 is so small. Since there is no need to perform other processing after the etching process, the complexity of the process can be reduced, the process time can be decreased, and the effect of increasing productivity and yield can be achieved.

The outer contours of the first surface 162 and the second surface 164 of the light-emitting diode chip 160 are substantially the same in shape and size, and the light-emitting diode chip 160 is not a type of wide top and a narrow bottom, so it can prevent the light-emitting diode chip 160 from tilting during transferring, thereby enhancing the transfer efficiency of the light-emitting diode chip 160.

In addition, the side surface 166 of the light-emitting diode chip 160 is substantially perpendicular to the first surface 162 and the second surface 164, such that when the light-emitting diode chips 160 are assembled in fluid, the light-emitting diode chips 160 do not block each other, thereby further enhancing the assembly efficiency of the light-emitting diode chips 160.

Furthermore, the sidewalls of the light-emitting diode chips 160 are substantially vertical, such that when these light-emitting diode chips 160 are assembled on a circuit board, the spacing between the light-emitting diode chips 160 is effectively decreased. Thus, it can make the display have better color rendering, and can also reduce the light interference between the light-emitting diode chips 160 of different colors. Moreover, the substantially vertical sidewall has a stronger structure than the conventional sidewall, which has a wide top and a narrow bottom and has an upper end with an acute angle, such that it can prevent the light-emitting diode chips 160 from being damaged during the transfer process.

Although the present disclosure has been described in considerable detail with reference to certain embodiments thereof, the foregoing embodiments of the present disclosure are illustrative of the present disclosure rather than limiting of the present disclosure. It will be apparent to those having ordinary skill in the art that various modifications and variations can be made to the present disclosure without departing from the scope or spirit of the disclosure. Therefore, the spirit and scope of the appended claims should not be limited to the description of the embodiments contained herein.

What is claimed is:

1. A light-emitting diode chip, comprising:
a light-emitting structure;
a first electrode disposed on the light-emitting structure and electrically connected to the light-emitting structure; and
a second electrode disposed on the light-emitting structure and located on a same side of the light-emitting structure as the first electrode, wherein the second electrode is electrically connected to the light-emitting structure,
wherein the light-emitting diode chip has a first surface and a second surface which are opposite to each other, and a side surface connected between the first surface and the second surface, and the side surface is substantially perpendicular to the first surface and the second surface.

2. The light-emitting diode chip of claim 1, wherein a substantially vertical included angle between the side surface and the first surface is between 86 degrees and 94 degrees.

3. The light-emitting diode chip of claim 1, wherein a substantially vertical included angle between the side surface and the first surface is between 88 degrees and 92 degrees.

4. The light-emitting diode chip of claim 1, wherein a length or a diameter of the light-emitting diode chip is less than 50 µm, and a thickness of the light-emitting diode chip is between 4 µm and 12 µm.

5. The light-emitting diode chip of claim 1, wherein a longer one and a short one of the first surface and the second surface respectively have a first length and a second length,
a difference between the first length and the second length divided by two is equal to or greater than 0, and
a difference between the first length and the second length divided by two is equal to or smaller than a height of the light-emitting diode chip divided by an absolute value of cot(a difference between 90 degrees and an included angle between the longer one and the side surface).

6. The light-emitting diode chip of claim 1, wherein outer contours of the first surface and the second surface are substantially the same in shape and size.

7. The light-emitting diode chip of claim 1, wherein a shape of the light-emitting diode chip is a circle or a symmetrical polygon.

8. The light-emitting diode chip of claim 1, wherein the light-emitting structure comprises a first conductive type semiconductor layer, a second conductive type semiconductor layer, and a light-emitting layer sandwiched between the first conductive type semiconductor layer and the second conductive type semiconductor layer, wherein the first electrode is electrically connected to the first conductive type semiconductor layer, and the second electrode is electrically connected to the second conductive type semiconductor layer.

9. A method for manufacturing light-emitting diode chips, comprising:
forming a light-emitting structure body on a growth substrate;
forming at least one barrier layer on the light-emitting structure body;
performing an etching process through the at least one barrier layer to remove a portion of the light-emitting structure body so as to form a plurality of light-emitting structures and to expose a portion of the growth substrate, wherein each of the light-emitting structures comprises a second conductive type semiconductor layer, a light-emitting layer, and a first conductive type semiconductor layer sequentially stacked on the growth substrate;
removing a first portion of the first conductive type semiconductor layer of the each of the light-emitting structures and the underlying light-emitting layer until a first portion of the second conductive type semiconductor layer is exposed;
forming a plurality of first electrodes respectively on a plurality of second portions of the first conductive type semiconductor layers of the light-emitting structures;
forming a plurality of second electrodes respectively on the first portions of the second conductive type semiconductor layers of the light-emitting structures to form a plurality of light-emitting diode chips, wherein each of the light-emitting diode chips has a first surface and a second surface which are opposite to each other, and a side surface connected between the first surface and the second surface, and the side surface is substantially perpendicular to the first surface and the second surface;
boding the light-emitting diode chips onto a temporary substrate by using an adhesive layer; and
removing the growth substrate to expose the second conductive type semiconductor layers.

10. The method of claim 9, wherein the at least one barrier layer is a compound composed of any combination of group III, group IV, and group V.

11. The method of claim 9, wherein the etching process is an inductively coupled plasma reactive ion etching process.

12. The method of claim 9, wherein outer contours of the first surface and the second surface of each of the light-emitting diode chips are substantially the same in shape and size.

13. The method of claim 9, wherein a shape of each of the light-emitting diode chips is a circle or a symmetrical polygon.

14. The method of claim 9, wherein in each of the light-emitting diode chips, a substantially vertical included angle between the side surface and the first surface is between 86 degrees and 94 degrees.

15. The method of claim 9, wherein in each of the light-emitting diode chips, a substantially vertical included angle between the side surface and the first surface is between 88 degrees and 92 degrees.

16. The method of claim 9, wherein in each of the light-emitting diode chips, a longer one and a short one of the first surface and the second surface respectively have a first length and a second length,
a difference between the first length and the second length divided by two is equal to or greater than 0, and
a difference between the first length and the second length divided by two is equal to or smaller than a height of the light-emitting diode chip divided by an absolute value of cot(a difference between 90 degrees and an included angle between the longer one and the side surface).
